(19) United States
(12) Patent Application Publication
(10) Pub. No.: US 2021/0351320 A1
(43) Pub. Date: Nov. 11, 2021

(54) Light-Emitting Element

(71) Applicant: SHARP KABUSHIKI KAISHA, Sakai City, Osaka (JP)

(72) Inventor: YOSHIHIRO UETA, Sakai City, Osaka (JP)

(21) Appl. No.: 17/286,675

(22) PCT Filed: Oct. 25, 2018
(86) PCT No.: PCT/JP2018/039643

§ 371 Date: Apr. 19, 2021

(51) Int. Cl. H01L 33/14; H01L 33/00

(52) U.S. Cl. CPC H01L 33/14; H01L 33/06; H01L 33/002

(57) ABSTRACT

A light-emitting element includes: a first electrode; a second electrode; a quantum dot layer provided between the first electrode and the second electrode, and containing quantum dots; and a hole-transport layer provided between the quantum dot layer and the first electrode, and containing a compound ZnM₂O₄ (where an element M is a metal element).

### TECHNICAL FIELD

The present invention relates to a light-emitting element containing quantum dots.

### BACKGROUND ART

Patent Document 1 discloses a light-emitting element including a hole-transport layer formed between an anode and a quantum dot layer.

### CITATION LIST

### Patent Literature

[Patent Document 1] Japanese Unexamined Patent Application Publication No. 2012-023388

### SUMMARY OF INVENTION

### Technical Problem

If, for example, the hole-transport layer of the light-emitting element is made of a conventional inorganic material, it is difficult to increase a hole density of the hole-transport layer. This problem causes an imbalance between electrons and holes to be transported to a quantum dot layer, possibly resulting in a decrease in light emission efficiency.

An aspect of the present invention is intended to provide a light-emitting element having high light emission efficiency.

### Solution to Problem

A light-emitting element according to an aspect of the present invention includes: a first electrode; a second electrode; a quantum dot layer provided between the first electrode and the second electrode, and containing quantum dots; and a hole-transport layer provided between the quantum dot layer and the first electrode, and containing a compound ZnM₂O₄ (where an element M is a metal element).

### BRIEF DESCRIPTION OF DRAWINGS

FIG. 1 illustrates a schematic cross-sectional view of a light-emitting device according to a first embodiment.

FIG. 2 illustrates an energy diagram showing an example of a Fermi level, or of an electron affinity and an ionization potential, of each layer in a light-emitting element of the light-emitting device according to Example 1-1.

FIG. 3 illustrates an energy diagram showing an example of a Fermi level, or of an electron affinity and an ionization potential, of each layer in a light-emitting element of the light-emitting device according to Example 1-2.

FIG. 4 illustrates an energy diagram showing an example of a Fermi level, or of an electron affinity and an ionization potential of, each layer in a light-emitting element of the light-emitting device according to Example 1-3.

FIG. 5 is a table showing results of Examples 1-1 to 1-11 and Comparative Example.

FIG. 6 illustrates a schematic cross-sectional view of a light-emitting device according to a second embodiment.

FIG. 7 illustrates an energy diagram showing an example of a Fermi level of, or of an electron affinity and an ionization potential of, each layer in a light-emitting element of the light-emitting device according to Example 2-1.

FIG. 8 is a table showing configurations and results of light-emitting elements according to Examples 2-1 to 2-3 and 3-1.

FIG. 9 illustrates a schematic cross-sectional view of a light-emitting device according to a third embodiment.

FIG. 10 illustrates an energy diagram showing an example of a Fermi level of, or of an electron affinity and an ionization potential of, each layer in a light-emitting element of the light-emitting device according to Example 3-1.

FIG. 11 illustrates a schematic cross-sectional view of a light-emitting device according to a fourth embodiment.

FIG. 12 illustrates an energy diagram showing an example of a Fermi level of, or of an electron affinity and an ionization potential of, each layer in a light-emitting element of the light-emitting device according to Example 4-1.

FIG. 13 is a table showing configurations and results of light-emitting elements according to Examples 4-1 to 4-21 and Comparative Examples.

### DESCRIPTION OF EMBODIMENTS

Described below are embodiments of the present invention, with reference to the drawings. Identical reference signs are used to denote identical or substantially identical components, and such identical components will not be elaborated upon.

### First Embodiment

FIG. 1 illustrates a schematic cross-sectional view of a light-emitting device 1 according to a first embodiment.

As illustrated in FIG. 1, the light-emitting device 1 according to this embodiment includes: a light-emitting element 2; and an array substrate 3. The light-emitting device 1 is structured to include the array substrate 3 in which not-shown thin-film transistors (TFTs) are formed, and the light-emitting element 2 multilayered and stacked on the array substrate 3. Note that, in DESCRIPTION, a direction from the light-emitting element 2 toward the array substrate 3 in the light-emitting device 1 is referred to as a “downward direction”, and a direction from the array substrate 3 toward the light-emitting element 2 in the light-emitting device 1 is referred to as an “upward direction”.

The light-emitting element 2 includes: a hole-transport layer 6; a quantum-dot layer 8; an electron-transport layer 10; and a second electrode 12 stacked, in the stated order from below, on top of a first electrode 4. The first electrode 4 included in the light-emitting element 2 formed above the array substrate 3 is electrically connected to the TFTs of the array substrate 3.

The first electrode 4 and the second electrode 12, containing a conductive material, are respectively and electrically connected to the hole-transport layer 6 and the electron-transport layer 10. In this embodiment, the first electrode 4 is an anode, and the second electrode 12 is a cathode.

Either the first electrode 4 or the second electrode 12 is a transparent electrode. The transparent electrode may be made of, for example, ITO, IZO, ZnO, AZO, BZO, or FTO and formed by, for example, sputtering. Moreover, either the first electrode 4 or the second electrode 12 may contain a metal material. The metal material preferably includes such a single-element metal as Al, Cu, Au, Ag, or Mg that is high in reflectance of visible light, or includes an alloy of these metals.

The quantum dot layer 8 includes quantum dots (semiconductor nanoparticles) 16. This quantum dot layer 8 may be either a single layer or a multilayer. In forming the quantum dot layer 8, the quantum dots 16 are dispersed in an organic solvent such as hexane or toluene so that a fluid disperse is produced. The fluid disperse is deposited by spin coating or ink-jet printing to form the quantum dot layer 8. Mixed with the fluid disperse may be a material in which such a substance as thiol or amine is dispersed. The quantum dot layer 8 preferably has a thickness ranging from 2 to 50 nm.

The quantum dots 16, having a valence band level and a conduction band level, is a light-emitting material emitting light by recombination of holes in the highest range of the valence band level and electrons in the lowest range of the conduction band level. The light emitted from the quantum dots 16 has a narrow spectrum because of the three-dimensional quantum confined effect. Hence, the emitted light can be relatively high in chromaticity.

An example of the quantum dots 16 may be semi-Cd-based conductive nanoparticles in a core-shell structure whose core includes CdSe and shell includes ZnS. Other than that, the quantum dots 16 may also include, as the core-shell structure, CdSe/CdS, InP/ZnS, ZnSe/ZnS, or CIGS/ZnS. Moreover, the quantum dots 16 may be made of Si, C, or a nitride-based compound. Furthermore, the quantum dots 16 may have a shell surface combined with a ligand.

The quantum dots 16 have a particle size ranging approximately from 2 to 15 nm. A wavelength of the light emitted from the quantum dots 16 can be controlled with the particle size of the quantum dots 16. Hence, through controlling the particle size of the quantum dots 16, the wavelength of the light emitted from the light-emitting device 1 can be controlled. In using the light-emitting device 1 for a display panel, the particles of the quantum dots emitting light in red, green and blue are preferably shaped uniformly.

The hole-transport layer 6 transports the holes from the first electrode 4 to the quantum dot layer 8. Moreover, in the light-emitting element 2 of this embodiment, the hole-transport layer 6 has one surface in contact with the first electrode 4 and another surface in contact with the quantum dot layer 8.

The hole-transport layer 6 contains a compound ZnM₂O₄ (where an element M is a metal element). The compound can increase a hole density of the hole-transport layer 6, contributing to transport of more holes from the hole-transport layer 6 to the quantum dot layer 8 and to improvement in light emission efficiency. The compound ZnM₂O₄ is preferably of a spinel structure (an octahedron with an edge-sharing structure). Furthermore, in order to increase the hole density of the hole-transport layer 6, the element M is preferably an element in group 9, and, more preferably, Co, Rh, and Ir. Moreover, the hole-transport layer 6 may contain two or more of the compounds ZnM₂O₄ each having the element M of a different metal element. In addition, the hole-transport layer 6 may be a multilayer including a plurality of layers containing the compounds ZnM₂O₄. Note that the hole-transport layer 6 according to this embodiment is a single layer. The hole-transport layer 6 as a multilayer will be described in second and third embodiments later.

The compound ZnM₂O₄ contained in the hole-transport layer 6 is preferably ZnRh₂O₄ and ZnIr₂O₄, and more preferably ZnIr₂O₄. This is because of the following findings; that is, the element M was replaced from Co to Rh, and to Ir while an amount of oxygen to be supplied was maintained at 5% in a film forming condition, and ZnCo₂O₄, ZnRh₂O₄, and ZnIr₂O₄ were each formed into a film. The films were checked for electrical characteristics. The results showed that ZnIr₂O₄ had the lowest resistance of 5 Ω·cm, followed by ZnRh₂O₄ of 8 Ω·cm, and ZnCo₂O₄ of 11 Ω·cm, and that ZnIr₂O₄ also had the highest hole density of 6×10¹⁸ cm⁻³, followed by ZnRh₂O₄ of 3×10¹⁸ cm³, and ZnCo₂O₄ of 9×10¹⁷ cm⁻³. The resistance and the hole density vary, depending on elements for the compound M. This is because an element in an upper group of the periodic table is less likely to block nuclei, causing a strong bond between valence electrons to increase energy for generating the holes.

Note that, among ZnCo₂O₄, ZnRh₂O₄, and ZnIr₂O₄, even ZnCo₂O₄ with the highest resistance and the lowest hole density has a hole density of approximately 10¹⁷ cm³. Hence, ZnCo₂O₄ still has a sufficient hole density as the hole-transport layer 6. Meanwhile, when the hole-transport layer 6 was made of NiO; that is, a conventional comparative material, the electric resistance was 1.8×10² Ω·cm, and the hole density was 2×10¹⁵ cm⁻³. In particular, the hole density failed to reach a practical level of 1×10⁷ cm⁻³.

Furthermore, when a typical wide gap semiconductor material whose band gap exceeds 4 eV is used for the hole-transport layer 6, the semiconductor material requires larger energy for activating the holes than thermal energy at room temperature, thereby posing difficulty in increasing hole density. Moreover, typically, the above wide gap semiconductor material is known to exhibit a phenomenon in which, even if a high concentration of accepter impurity is added to the wide gap material, the holes are compensated for the electrons naturally generated to have approximately the same concentration as that of the accepter impurity, thereby also posing difficulty in increasing hole density.

However, even though the band gaps of the above ZnIr₂O₄, ZnRh₂O₄, and ZnCo₂O₄ are respectively 2.5 eV, 3.1 eV, and 4.0 eV that are close to a band gap of the wide gap semiconductor material, the hole-transport layer formed of ZnIr₂O₄, ZnRh₂O₄, and ZnCo₂O₄ as described above can increase the hole density, compared with the hole density of, for example, 2×10¹⁵ cm⁻³ observed when the hole-transport layer is formed using NiO as a conventional wide gap semiconductor material.

Moreover, when the hole-transport layer 6 contains ZnIr₂O₄, the operating voltage is 3.1 V. With reference to ZnIr₂O₄, the operating voltage is approximately higher by 0.2 V with ZnRh₂O₄, and by 0.3 V with ZnCo₂O₄. The reason is that a difference in ionization potential between the hole-transport layer 6 and ITO; namely, the first electrode 4, varies, depending on a material of the hole-transport layer 6. Moreover, when the element M of ZnM₂O₄ is replaced from Ir to Rh, and to Co. the difference in ionization potential increases in the stated order. Compared with a hole-transport layer made of NiO in a conventional technique, even the hole-transport layer 6 made of ZnCo₂O₄ can achieve an improvement in characteristic. The material of the hole-transport layer 6 is preferably ZnRh₂O₄, and more preferably, ZnIr₂O₄.

The hole-transport layer 6 preferably has a thickness ranging from 1 to 40 nm. An experiment by the inventors showed that if the hole-transport layer 6 had a thickness less than 1 nm, the hole-transport layer 6 observed with, for example, a transmission electron microscope (TEM) had a cross-section not shaped in a uniform film but in an island. If the hole-transport layer 6 is shaped into an island with a thickness of less than 1 nm on average, electrical and mechanical contact could be insufficient between the hole-transport layer 6 and the first electrode 4, and between hole-transport layer 6 and the quantum dot layer 8. The insufficient contact could cause such unfavorable phenomena as a rise in operating voltage, a fall in upper limit of a drive current, and delamination of the first electrode 4. Moreover, if the hole-transport layer 6 has a thickness of more than 40 nm, the series resistance rises, which raises voltage and power consumption and results in an increase in amount of generated heat. Such problems could unfavorably affect power conversion efficiency and long-term reliability of the light-emitting device 1. Furthermore, if the hole-transport layer 6 has a thickness of more than 40 nm, a current flowing throughout a face of the hole-transport layer 6 increases. When a display panel is produced using the light-emitting device 2 of this embodiment, the increased current could cause cross-talk between neighboring light-emitting regions in the display panel. Note that, if the hole-transport layer 6 is a multilayer stack, each of the layers included in the hole-transport layer 6 preferably has a thickness of 1 nm or more and 40 nm or less.

Preferably, the hole-transport layer 6 is transparent and absorbs very little visible light when observed by spectroscopy, so that the hole-transport layer 6 preferably has a light transmittance of 95% or higher. Such features make it possible to keep the hole-transport layer 6 from attenuating light emitted outside.

The hole-transport layer 6 can be formed by such techniques as sputtering and coating. In producing, for example, a liquid crystal display panel, sputtering is utilized to form a transparent electrode and a TFT, so that a large sputtering apparatus can be directly used for manufacturing a large-area substrate from which a plurality of large panels having a diagonal size of 50 inches or more can be cut out. Moreover, a material of the hole-transport layer 6 is processed into nano-sized particulates. The nano-sized particulates are dispersed into a solvent so that a colloidal solution is prepared. The hole-transport layer 6 can be formed by application of the colloidal solution. Furthermore, a compound serving as a precursor of the hole-transport layer 6 can be applied and baked to be the hole-transport layer 6. Any one of such techniques can reduce production costs.

The hole-transport layer 6 can be formed, in particular, by sputtering. When sputtering is utilized to form the hole-transport layer 6, oxygen to be supplied during the sputtering is adjusted to preferably account for 70% or more and 90% or less of the total amount of a gas to be supplied. If the supplied oxygen accounts for more than 90% of the total amount of the supplied gas, the plasma is not stable and the sputtering rate varies. Such a problem could pose a difficulty in stable formation of the hole-transport layer 6. Whereas, if the supplied oxygen accounts for less than 70% of the total amount of the supplied gas, the hole density falls such that an unfavorable case could arise. When the hole-transport layer 6 made of ZnM₂O₄ (where M is Co, Rh, and Ir) was formed with a sputtering apparatus whose reactor had a volume of 5 m³, an amount of oxygen gas to be supplied was adjusted in a range from 14 cc/min to 18 cc/min (70% or more and 90% or less) with respect to the total amount of gas of 20 cc/min to be supplied to the sputtering apparatus. The formed hole-transport layer 6 had a thickness of approximately 1 μm. When electrically evaluated, the hole-transport layer 6 exhibited p-type conductivity whose hole density was 6×10¹⁸ cm³. Based on a fact that the hole density was 2×10¹⁶ cm; when the oxygen gas was supplied in an amount of 6 cc/min (i.e. 30%), the above adjustment of the oxygen clearly shows an increase in hole density. Film specimens of the hole-transport layer 6 were transparent in appearance, and absorbed very little visible light when observed by spectroscopy. The light transmittance of the film specimens was confirmed to be 95% or higher. Note that the p-type conductivity is probably due to the holes of Zn or Ir-substituted Zn.

Furthermore, in forming the hole-transport layer 6, sputtering is utilized to reduce power consumption. This technique can also increase the hole density of the hole-transport layer 6. The technique reduces kinetic energy of atoms included in such a sputtering gas as ionized Ar. Hence, when a target is sputtered, the atoms included in the target are less likely to be ejected. As a result, oxygen, the only gas element included in the target, is preferentially ejected. Thus, when the power consumption for the sputtering is reduced, the oxygen is lost, contributing to an increase in hole density. Moreover, in forming the hole-transport layer 6, sputtering is utilized to previously shift a composition of the target from composition stoichiometry to a composition with higher oxygen. This technique can also increase the hole density of the hole-transport layer 6.

Here, conductive organic compounds were often used as the hole-transport layer 6. The conductive organic compounds, however, exhibit extremely lower mobility of holes than a typical conductive inorganic material such as metal or semiconductor does. Hence, if a potential difference occurs when the hole-transport layer 6 made only of a conductive organic composition is adopted to, for example, a light-emitting element, a space-charge layer might be formed in the hole-transport layer 6. The voltage-current characteristics here do not exhibit ohmic characteristics so that a current is not proportional to voltage/layer thickness. Alternatively, the voltage-current characteristics exhibit non-linearly space-charge-limited characteristics so that a current is proportional to dielectric constant×mobility×voltage²/layer thickness³. Because the product of the dielectric constant and the mobility is extremely low, the absolute value of the current due to the space-charge-limited characteristics is small and inversely proportional to the cube of the layer thickness. Hence, the current varies extremely sensitively with respect to distribution of the layer thickness. Moreover, if the layer thickness is in the order of nanometers, an electric field to be applied to the hole-transport layer is extremely high to be in the order of MV/cm even though a drive voltage is several volts. These findings show that, in a light-emitting element using a hole-transport layer made of a conductive organic compound, the voltage-current characteristics and light-emission characteristics react extremely sensitively to variation or distribution in a thickness of the hole-transport layer. Such a characteristic makes it difficult for a light-emitting device to stably emit light. Moreover, since the electric field to be applied to the hole-transport layer is large, it is inevitable that the hole-transport layer is potentially susceptible to electrostatic breakdown. Furthermore, the organic compound deteriorates by oxidation. In order to ensure a long term reliability of the hole transport layer, the hole transport layer has to be tightly sealed and protected from oxygen or water in the air.

Thus, in this embodiment, the hole-transport layer 6 preferably contains an inorganic material, and is more preferably, made of an inorganic material. Compared with a hole-transport layer that consists only of an organic material, the hole-transport layer 6 can exhibit an improvement in carrier mobility. Moreover, inorganic materials are more resistant in oxidization than organic materials. In particular, the hole-transport layer of the present application itself is a very stable oxide, and is extremely resistant in deterioration and changes over time caused by, for example, oxygen, an OH radical, ozone, or ultraviolet in the air. Hence, the light-emitting element 2 according to this embodiment can reduce the risk of electrostatic breakdown and achieve high dependability at low costs.

The electron-transport layer 10 transports electrons from the second electrode 12 to the quantum dot layer 8. In order to confine holes in the quantum dot layer 8, the electron-transport layer 10 may also function to block transportation of the holes. The electron-transport layer 10 may contain, for example, such a substance as ZnO, TiO₂, Ta₂O₃, SrTiO₃, or an electrode. Similar to the hole-transport layer 6, the electron-transport layer 10 can be formed by sputtering and by coating and baking. The electron-transport layer 10 may have a typically known thickness, preferably ranging from 1 to 100 nm. An experiment of the inventors shows that, if a thickness of the electron-transport layer 10 is 1 nm or less when the electron-transport layer 10 is formed by, for example, sputtering, the electron-transport layer 10 is often shaped not into a monolithic film but into an island. This could cause the same problem as the hole-transport layer 6 has. Moreover, if the thickness of the electron-transport layer 10 is 100 nm or more, the electron-transport layer 10 is likely to absorb more light emitted from the quantum dot layer 8. This might not be favorable because the greater thickness affects characteristics, in particular, external quantum efficiency, of the light-emitting element. Furthermore, the electron-transport layer 10 is preferably formed thinner unless otherwise affecting electrical characteristics of the electron-transport layer 10.

The hole-transport layer 6 and the electron-transport layer 10 may be each formed of nanoparticle crystal, crystal, polycrystal, or amorphous. Here, the amorphous is a state in which, when surroundings are observed from any given atom, a short-range order of approximately a second proximity to a third proximity is maintained, and a long-range order over a fourth proximity is out of alignment. In particular, the compound ZnM₂O₄ contained in the hole-transport layer 6 according to this embodiment preferably maintains atomic bonds of the spinel crystals (i.e. the spinel structure) as long as at least a short-range order is maintained. Furthermore, in order not to inhibit emission of light from the light-emitting element 2, the hole-transport layer 6 and the electron-transport layer 10 preferably have an absorption coefficient of 10 cm⁻¹ or smaller with respect to emission of light from the quantum dot layer 8.

Described below is how the light-emitting device 1 according to this embodiment emits light, with reference to FIG. 1. In the light-emitting device 1, a potential difference is applied between the first electrode 4 and the second electrode 12, such that holes and electrons are respectively injected from the first electrode 4 and the second electrode 12 toward the quantum dot layer 8. As an arrow h⁺ in FIG. 1 indicates, the holes from the first electrode 4 travel through the hole-transport layer 6, and reach the quantum dot layer 8. As an arrow e in FIG. 1 indicates, the electrons from the second electrode 12 travel through the electron-transport layer 10, and reach the quantum dot layer 8. The holes and the electrons reaching the quantum dot layer 8 recombine in the quantum dots 16 and emit light.

Note that, in the light-emitting device 2 of this embodiment, the light emitted from the quantum dots 16 may be reflected on the second electrode 12, which is, for example, a metal electrode. The reflected light may pass through the first electrode 4, which is a transparent electrode, and the array substrate 3, and then may be released out of the light-emitting device 1. On the contrary, the first electrode 4 may be a reflective electrode and the second electrode 12 may be a transparent electrode, so that the light may be emitted from the second electrode 12. Moreover, the layers from the array substrate 3 to the second electrode 12 may be stacked in the reverse order. Hence, the second electrode, the electron-transport layer, the quantum dot layer, the hole-transport layer, and the first electrode may be stacked in the stated order, and either the first electrode or the second electrode may be a reflective electrode so that the light may be emitted from a transparent electrode across from the reflective electrode.

This embodiment will be described more specifically below, with reference to Examples and Comparative Example.

### Example 1-1

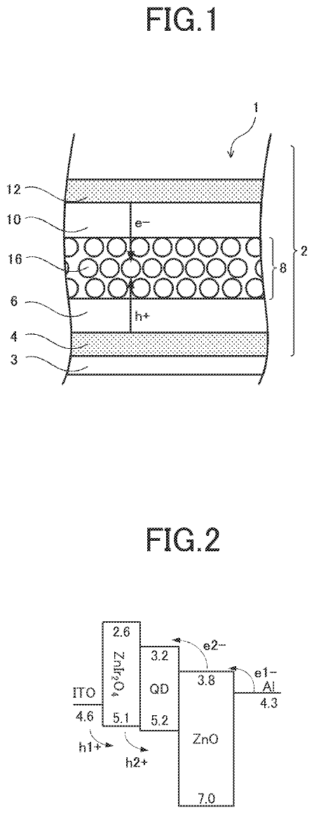

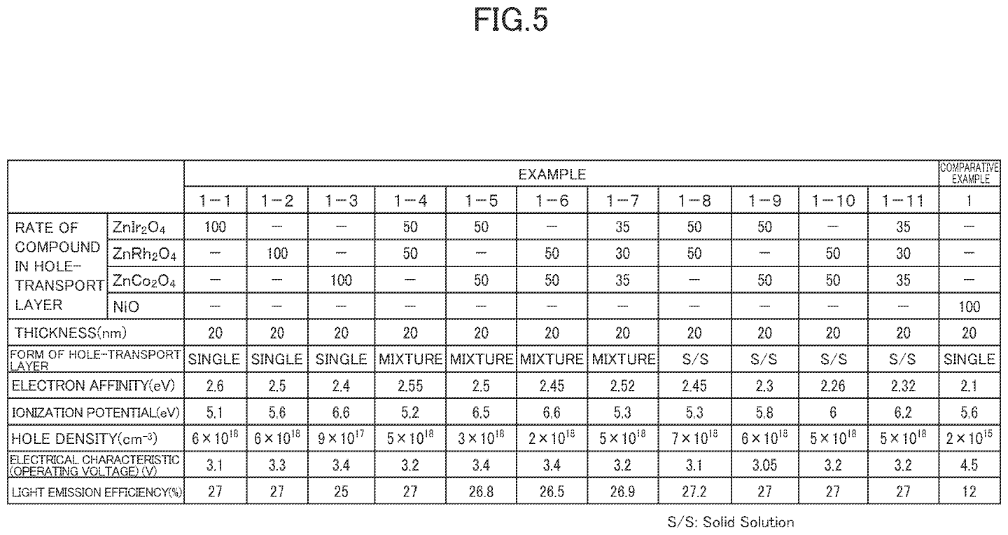

In this example, a light-emitting element is produced, using the hole-transport layer 6 formed of the compound ZnIr₂O₄. This light-emitting element is described, with reference to FIG. 2. As illustrated in FIG. 1, the hole-transport layer 6 in this example is a single layer. The compound ZnIr₂O₄ is of a spinel structure. Note that the hole-transport layer 6 is formed by sputtering, and the characteristics of the hole-transport layer 6 are shown in the table of FIG. 5. Similar to this example, also shown in the table 5 of FIG. 5 are the characteristics of Comparative Example 1 in which the hole-transport layer is formed of NiO.

FIG. 2 illustrates an energy diagram showing an example of an electron affinity and an ionization potential of each layer of the light-emitting element in this example when the hole-transport layer 6 is made of ZnIr₂O₄. FIG. 2 shows from left to right the first electrode 4, the hole-transport layer 6, the quantum dot layer 8, the electron-transport layer 10, and the second electrode 12. In this example, as an example, the first electrode 4 is made of ITO, the second electrode 12 is made of Al, and the electron-transport layer 10 is made of ZnO.

As to the first electrode 4 and the second electrode 12, a Fermi level of each electrode is represented in eV. In lower portions of the hole-transport layer 6, the quantum dot layer 8, and the electron-transport layer 10, an ionization potential of each layer is represented in eV with reference to the vacuum level. In upper portions of the hole-transport layer 6, the quantum dot layer 8, and the electron-transport layer 10, an electron affinity of each layer is represented in eV with reference to the vacuum level.

Moreover, the values of the energy levels of the quantum dots in FIG. 2 represent values of the cores of the quantum dots 16. Shells of the quantum dots 16 are extremely thin in the order of nanometers, and function to protect the cores and confine injected electron-hole pairs into the cores so that the electron-hole pairs recombine in the cores and emit light. When observed from outside, thin shells cannot serve as a barrier for the injection of the electrons and the holes, and thus may be ignored. Hence, all the electron affinities, ionization potentials, and Fermi levels in FIG. 2 and other energy diagrams in the present application represent the values of the cores.

In this DESCRIPTION, hereinafter, description of the ionization potential or the electron affinity alone is made with reference to the vacuum level.

FIG. 2 shows that, in the light-emitting element 2 of this example, the hole-transport layer 6 has an ionization potential of 5.1 eV and an electron affinity of 2.6 eV. Moreover, the electron-transport layer 10 has an ionization potential of 7.0 eV and an electron affinity of 3.8 eV. Furthermore, in this example, the quantum dot layer 8 has an ionization potential of, for example, 5.2 eV and an electron affinity of 3.2 eV even though the ionization potential and the electron affinity vary depending on the material and particle size of the quantum dots 16.

Described below is how the holes and the electrons are transported in the layers of the light-emitting element 2, with reference to FIG. 2.

In the light-emitting element 2, when the potential difference occurs between the first electrode 4 and the second electrode 12, the holes are transported from the first electrode 4 to the hole-transport layer 6 as indicated by an arrow h1⁺ in FIG. 2. Next, the holes are transported from the hole-transport layer 6 to the quantum dot layer 8 as indicated by an arrow h2⁺ in FIG. 2. Here, for example, a barrier in transport of the holes from the hole-transport layer 6 to the quantum dot layer 8 is indicated by an energy obtained as a difference when the ionization potential of the hole-transport layer 6 is subtracted from the ionization potential of the quantum dots 16. Hence, the barrier in the hole transport of this example is 0.1 eV.

Meanwhile, the electrons are transported from the second electrode 12 to the electron-transport layer 10 as indicated by an arrow e1⁻ in FIG. 2. Next, the electrons are transported from the electron-transport layer 10 to the quantum dot layer 8 as indicated by an arrow e2⁻ in FIG. 2.

As can be seen, the holes and the electrons transported to the quantum dot layer 8 recombine in the quantum dots 16 and emit light.

Note that the recombination in the quantum dots 16 is classified into light-emitting recombination and non-light-emitting recombination. The non-light-emitting recombination produces not light but heat, which is a cause of a decrease in internal quantum efficiency. Hence, the internal quantum efficiency is maximized when the recombination process in the quantum dots involves only the light-emitting recombination. Usually, the non-light-emitting recombination occurs through a relatively deep level formed inside the band gap by lattice defect and impurities. Thus, quality of the quantum dots 16 is important. Moreover, when the electrons and the holes are of the same concentration in the quantum dot layer 8, the electrons and the holes can recombine together in neither an excessive manner nor an insufficient manner. Hence, the quantum efficiency is maximized when the electrons and the holes to be transported are of the same concentration. In a conventional quantum-dot light-emitting element, electrons are injected more readily than holes are, and the quantum dot layer 8 is likely to be excessively supplied with electrons. The excessive electrons that cannot recombine with holes only flow through the light-emitting element, such that most of the electrons to be transported to the quantum dot layer 8 outflow without contributing to emission of light.

Here, the barrier in the hole transport from the hole-transport layer 6 to the quantum dots 16 of this embodiment is 0.1 eV, which is much smaller than a barrier of 0.6 eV in Comparative Example. Hence, the holes can be efficiently transported from the hole-transport layer 6 to the quantum dot layer 8.

Furthermore, in this example, a potential difference can be reduced in a p-i-n junction of the hole-transport layer 6, the quantum dot layer 8, and the electron-transport layer 10 joining together. Accordingly, the holes can be transported with a lower voltage since a voltage of 3.1 V is required for the transport of the holes in this example; whereas, a voltage of 4.5 is required in Comparative Example 1. As can be seen, when the voltage required for the hole transport decreases, the light-emitting element 2 can reduce its power consumption that is proportional to the square of the voltage. The reduction in power consumption can reduce heat to be generated in the light-emitting element 2. Note that the quantum dot layer 8 of the p-i-n junction is denoted by “i” because the quantum dot layer 8 is not doped and the Fermi level is fixed near the center of the band gap, so that free carriers are not generated at room temperature. Moreover, as the table of FIG. 5 shows, the hole-transport layer 6 of this embodiment makes it possible to achieve a higher hole density, a lower electrical characteristic, and a higher light emission efficiency than those of Comparative Example.

Hence, the light-emitting element 2 according to this example can improve efficiency in transport of the holes from the first electrode 4 to the quantum dot layer 8, and efficiently recombine the holes transported to the quantum dot layer 8 with the electrons transported from the second electrode 12 to the quantum dot layer 8. Such features make it possible to improve the light emission efficiency and the power conversion efficiency of the light-emitting element 2 according to this example.

### Example 1-2

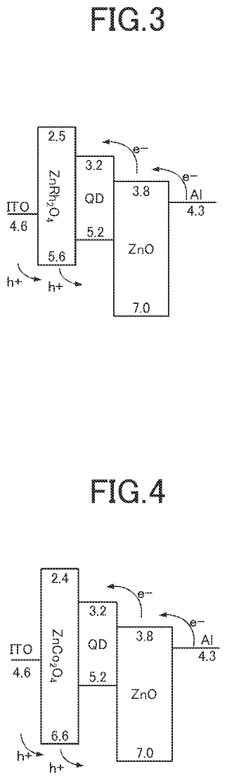

This example is different from Example 1-1 in that the hole-transport layer 6, used for production of a light-emitting element, is formed of the compound ZnRh₂O₄. This light-emitting element is described, with reference to FIG. 3. As illustrated in FIG. 1, the hole-transport layer 6 in this example is a single layer. The compound ZnRh₂O₄ is of a spinel structure. Note that the hole-transport layer 6 is formed by sputtering, and the characteristics of the hole-transport layer 6 are shown in the table of FIG. 5.

FIG. 3 shows that, in the light-emitting element 2 of this example, the hole-transport layer 6 has an ionization potential of 5.6 eV and an electron affinity of 2.5 eV. Here, the barrier in the hole transport from the hole-transport layer 6 to the quantum dots 16 of this embodiment is −0.4 eV, which is much smaller than a barrier of 0.6 eV in Comparative Example. Hence, the holes can be efficiently transported from the hole-transport layer 6 to the quantum dot layer 8.

Moreover, as the table of FIG. 5 shows, the hole-transport layer 6 of this embodiment makes it possible to achieve a higher hole density, a lower electrical characteristic, and a higher light emission efficiency than those of Comparative Example.

### Example 1-3

This example is different from Example 1-1 in that the hole-transport layer 6, used for production of a light-emitting element, is formed of the compound ZnCo₂O₄. This light-emitting element is described, with reference to FIG. 4. As illustrated in FIG. 1, the hole-transport layer 6 in this example is a single layer. The compound ZnCo₂O₄ is of a spinel structure. Note that the hole-transport layer 6 is formed by sputtering, and the characteristics of the hole-transport layer 6 are shown in the table of FIG. 5.

FIG. 4 shows that, in the light-emitting element 2 of this example, the hole-transport layer 6 has an ionization potential of 6.6 eV and an electron affinity of 2.4 eV. Here, the barrier in the hole transport from the hole-transport layer 6 to the quantum dots 16 of this embodiment is −1.4 eV, which is much smaller than a barrier of 0.6 eV in Comparative Example. Hence, the holes can be efficiently transported from the hole-transport layer 6 to the quantum dot layer 8.

Moreover, as the table of FIG. 5 shows, the hole-transport layer 6 of this embodiment makes it possible to achieve a higher hole density, a lower electrical characteristic, and a higher light emission efficiency than those of Comparative Example.

Examples 1-4 to 1-11 These examples are different from Example 1-1 in that the hole-transport layers 6, used for production of light-emitting elements, are formed of a mixture or a solid solution of two of, or all of, the compounds ZnIr₂O₄, ZnRh₂O₄, and ZnCo₂O₄. The characteristics of the hole-transport layers are also shown in the table of FIG. 5. Note that, as Examples 1-4 to 1-7 show, the hole-transport layers 6 made of a mixture are formed by three-target sputtering using the compounds ZnIr₂O₄, ZnRh₂O₄, and ZnCo₂O₄ as independent targets, while the amount of oxygen to be supplied in the formation of the layers is adjusted to account for 70% or more and 90% or less of the total amount of gas. Note that, in these examples, the hole-transport layers 6 are formed by three-target sputtering. Alternatively, the targets for sputtering may be formed of a mixture of the three compounds. Moreover, as Examples 1-8 to 1-11 show, the hole-transport layers 6 made of a solid solution can be formed by reactive sputtering, using Zn, Ir, Rh, and Co as independent targets and supplied with oxygen.

As the table of FIG. 5 shows, the hole-transport layers 2, formed of a mixture, a solid solution, and a multilayer of two or more materials, make it possible to achieve a higher hole density, a lower electrical characteristic, and a higher light emission efficiency than those of Comparative Example. As to the electric characteristics, the results of Examples 1-4 to 1-11 are not different from those of Examples 1-1 to 1-3 in which the compounds are not mixed together. Hence, the hole-transport layers made of a mixture are each an aggregate in which microparticles of the substances are mixed together at random. Here, the holes are transported between neighboring particles in contact with each other, which is not interpreted as hopping conduction between the particles. Furthermore, if the hole-transport layers are made of a solid solution, any given two or all of the elements M; namely, Ir, Rh, and Co, are uniformly distributed without individually deposited. As a matter of course, the holes of the solid solution are transported not by hopping conduction but by a drift current due to an applied electric field.

### Second Embodiment

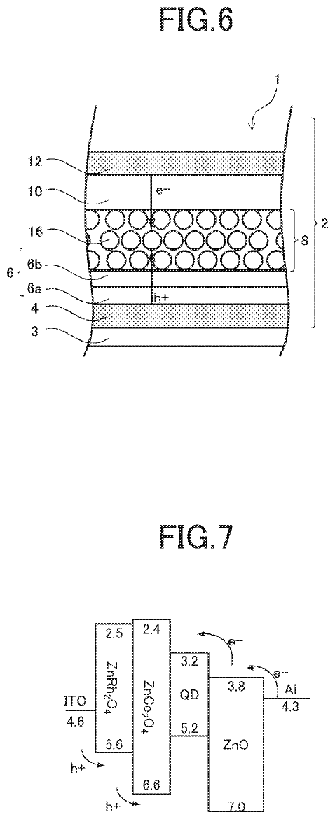

FIG. 6 illustrates a schematic cross-sectional view of the light-emitting device 1 according to this embodiment. The only difference between the light-emitting device 1 according to this embodiment and the light-emitting device 1 according to the first embodiment is that, in the former, the hole-transport layer 6 includes a plurality of layers 6a and 6b.

This embodiment will be described more specifically below, with reference to Examples and Comparative Example.

### Examples 2-1 to 2-3

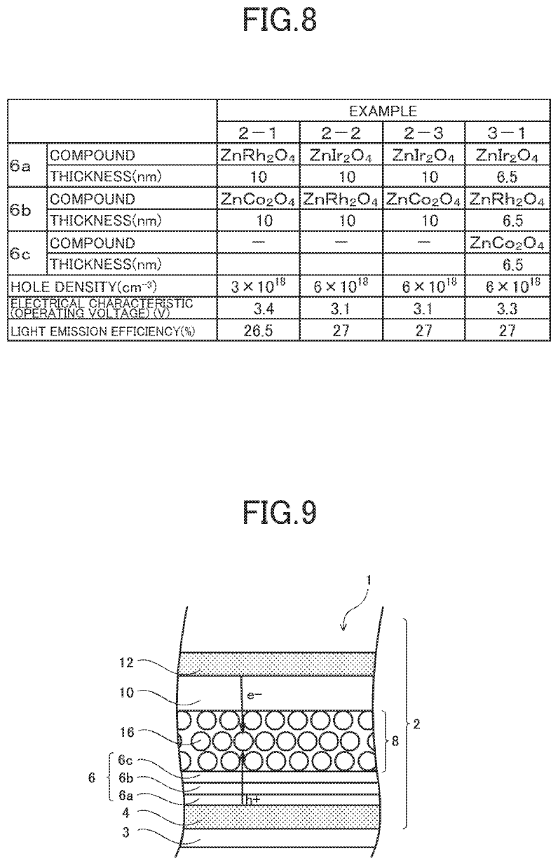

In Example 2-1, a light-emitting element is produced, using the compound ZnRh₂O₄ as the hole-transport layer 6a and the compound ZnCo₂O₄ as the hole-transport layer 6b. This light-emitting element is described, with reference to FIG. 7. Note that the hole-transport layers 6a and 6b are formed by sputtering, and the characteristics of the hole-transport layers and the light-emitting element are shown in the table of FIG. 8. The hole-transport layers 6a and 6b are stacked so that the ionization potential increases from the first electrode 4 toward the quantum dot layer 8. This configuration makes it possible to efficiently inject the holes from the hole-transport layers 6 to the quantum dot layer 8. Likewise, the hole-transport layers 6a and 6b are stacked so that the electron affinity decreases in a direction from the first electrode 4 toward the quantum dot layer 8. This configuration makes it possible to efficiently inject the holes from the hole-transport layers 6 to the quantum dot layer 8. Moreover, in Examples 2-2 and 2-3 as other examples, two of the compounds ZnIr₂O₄, ZnRh₂O₄, and ZnCo₂O₄ are selected as the hole-transport layers 6, and light-emitting elements are produced in a similar manner. The characteristics of the hole-transport layers and the light-emitting elements are also shown in the table of FIG. 8.

As the table of FIG. 8 shows, the hole-transport layers 6 (6a and 6b) of these examples make it possible to achieve a higher hole density, a lower electrical characteristic, and a higher light emission efficiency than those of Comparative Example.

### Third Embodiment

FIG. 9 illustrates a schematic cross-sectional view of the light-emitting device 1 according to this embodiment. The only difference between the light-emitting device 1 according to this embodiment and the light-emitting device 1 according to the first embodiment is that, in the former, the hole-transport layer 6 includes a plurality of layers 6a, 6b, and 6c.

This embodiment will be described more specifically below, with reference to Examples and Comparative Example.

### Example 3-1

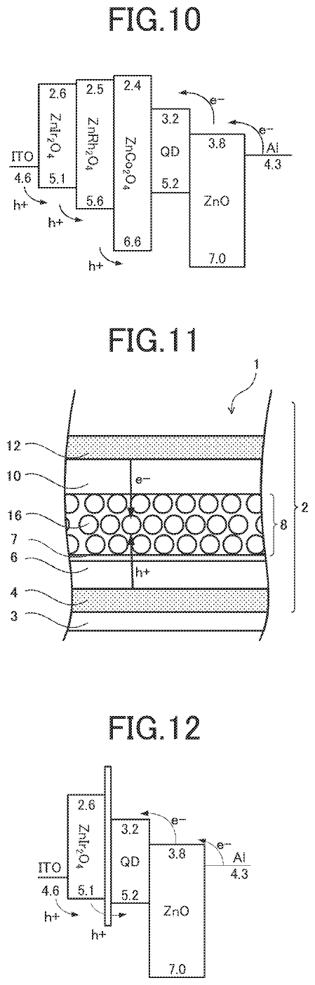

In this example, a light-emitting element is produced, using the compound ZnIr₂O₄ as the hole-transport layer 6a, the compound ZnRh₂O₄ as the hole-transport layer 6b, and the compound ZnCo₂O₄ as the hole-transport layer 6b. This light-emitting element is described, with reference to FIG. 10. Note that the hole-transport layers 6a, 6b, and 6c are formed by sputtering, and the characteristics of the hole-transport layers and the light-emitting element are shown in the table of FIG. 8. The hole-transport layers 6a, 6b, and 6c are stacked so that an ionization potential increases in a direction from the first electrode 4 toward the quantum dot layer 8. This configuration makes it possible to efficiently inject the holes from the hole-transport layer 6 to the quantum dot layer 8. Likewise, the hole-transport layers 6a, 6b, and 6c are stacked so that an electron affinity decreases in a direction from the first electrode 4 toward the quantum dot layer 8. This configuration makes it possible to efficiently inject the holes from the hole-transport layer 6 to the quantum dot layer 8.

As the table of FIG. 8 shows, the hole-transport layers 6 (6a, 6b, and 6c) of these examples make it possible to achieve a higher hole density, a lower electrical characteristic, and a higher light emission efficiency than those of Comparative Example.

### Fourth Embodiment

FIG. 11 illustrates a schematic cross-sectional view of the light-emitting device 1 according to this embodiment. A difference between the light-emitting device 1 according to this embodiment and the light-emitting device 1 according to the first embodiment is that, in the former, an intermediate layer 7 is provided between the hole-transport layer 6 and the quantum dot layer 8.

The intermediate layer 7 blocks a leak of electrons from the quantum dot layer 8 toward the hole-transport layer 6. Preferably, the intermediate layer 7 is formed of a metal oxide such as a compound L₂O₃ (where an element L is a metal element, and, preferably, Al, Ga, and In among the elements in group 13). In the L₂O₃ metal oxide, the element L has a valence of four combining with oxygen in neither an excessive manner nor an insufficient manner. Tight bonding of the oxygen and the element in group 13 makes the metal oxide a very stable substance. Here, a crystal of the compound L₂O₃, either a rhombohedron or a monoclinic crystal, is bound tightly and insulating. Note that if the element L is Al in an upper group of the periodic table, the compound Al₂O₃ is particularly highly insulating. Hence, the compound Al₂O₃ is particularly preferable as the intermediate layer 7. Moreover, the L₂O₃ metal oxide is highly transparent to visible light to near-ultraviolet light. Because of such features, the L₂O₃ metal oxide is suitable as a material of light-emitting elements.

The intermediate layer 7 can be formed by such techniques as sputtering and coating with colloidal nanoparticles. Moreover, when the intermediate layer 7 is formed by sputtering, a material of L₂O₃ may be selected as a target including such metals as Al, Ga, and In. The intermediate layer 7 may also be formed by reactive sputtering, using such a sputtering gas as Ar with oxygen added. Furthermore, a metal film may be formed using the metals Al, Ga, and In as a target, and may be oxidized to form a compound. Note that in using Ga, attention should to be paid to its melting point because the ambient temperature needs to be maintained below the melting point.

### Example 4-1

In this example, a light-emitting element is produced in accordance with Example 1-1. The light-emitting element includes the intermediate layer 7 formed of Al₂O₃ having a thickness of 2 nm. The intermediate layer 7 is formed by sputtering. This light-emitting element is described, with reference to FIG. 12. FIG. 12 illustrates an energy level of each layer in Example 4-1 of the element whose schematic cross-sectional view is illustrated in FIG. 11. In the drawing, each layer is illustrated as a bar with an ionization potential and an electron affinity respectively put on the bottom end and the top end of the bar. Moreover, the electrodes are each illustrated with a work function.

FIG. 12 shows that, in the light-emitting element 2 of this example, the hole-transport layer 6 has an ionization potential of 5.1 eV and an electron affinity of 2.6 eV. Here, the barrier in the hole transport from the hole-transport layer 6 to the quantum dots 16 of this embodiment is −0.4 eV, which is much smaller than a barrier of 0.6 eV in Comparative Example 1. Hence, the holes can be efficiently transported from the hole-transport layer 6 to the quantum dot layer 8.

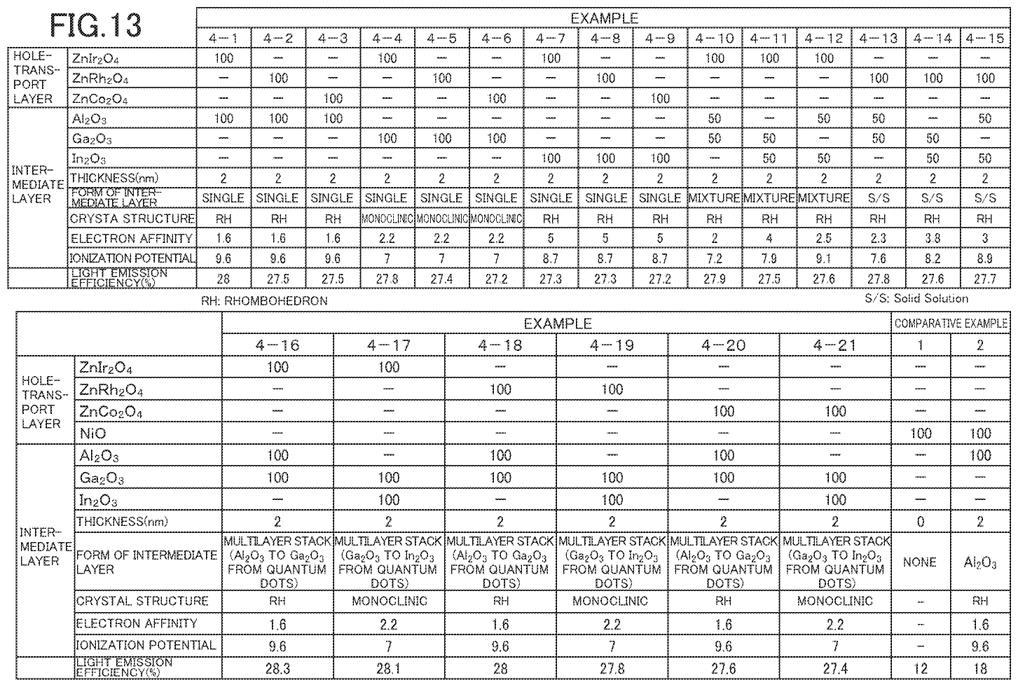

FIG. 13 shows results of the measurement of, for example, light emission efficiency of the light-emitting element according to this example. As can be seen from the table of FIG. 13, the hole-transport layer 6 of this example achieves high light emission efficiency compared with a case without the intermediate layer 7.

### Examples 4-2 to 4-21

As illustrated in FIG. 13, light-emitting elements are produced in a similar manner as Example 4-1, while materials of the hole-transport layer 6 (e.g. ZnIr₂O₄, ZnRh₂O₄, and ZnCo₂O₄) and the intermediate layer 7 (e.g. Al₂O₃, Ga₂O₃, and In₂O₃) are modified. FIG. 13 shows results of the measurement of light emission efficiency of the light-emitting elements according to Examples 4-2 to 4-21. As seen in the tables of FIG. 13, Examples 4-2 to 4-21 each show a light emission efficiency of over 20%. Compared with a case where no intermediate layer 7 is formed, the examples exhibit a further increase in light emission efficiency. The increase in light emission efficiency is due to the effect of the intermediate layer 7 The materials of the intermediate layer 7 are very stable and highly insulating metal oxides. When provided between the hole-transport layer 6 and the quantum dot layer 8, the intermediate layer 7 deactivates a dangling bond and a lattice defect exposed on the surface of the layers. That is why the holes are injected from the hole-transport layer 6 to the quantum dot layer 8 without being caught by the dangling bond and the lattice defect.

Furthermore, as Examples 4-2 to 4-21 of the tables in FIG. 13 show, the intermediate layer 7 is formed: not only of Al₂O₃, but also of Ga₂O₃ and In₂O₃; of a mixture, and of a solid solution, of at least two materials selected from among Al₂O₃, Ga₂O₃, and In₂O₃; and of a multilayer stack of Al₂O₃, Ga₂O₃, and In₂O₃. Compared with a case where no intermediate layer 7 is formed, the examples can exhibit an increase in light emission efficiency. Note that FIG. 13 shows such results as light emission efficiency of Comparative Example 1 in which NiO is formed as a hole-transport layer, and of Comparative Example 2 in which Example 1 is provided with an intermediate layer formed of Al₂O₃.

The intermediate layer 7 preferably has a thickness of 0.5 or more and less than 10 nm. This is found out from the results of evaluating the light emission efficiency with the thickness of the intermediate layer 7 varied. A decrease in light emission efficiency is confirmed when the intermediate layer 7 has a film thickness of 0.5 nm or less; that is, 0.4 nm. When this specimen is observed with a TEM, the cross-section of the intermediate layer 7 is shaped into an island that is not uniformed or monolithic. Because of these findings, the holes passing through the non-monolithic region of the intermediate layer 7 are expected to be caught in the defects of the hole-transport layer 6 and the quantum dot layer 8. Hence, the intermediate layer 7 is preferably formed monolithically throughout the light-emitting element. Next, when the thickness of the intermediate layer 7 is increased, the drive voltage tends to start rising when the thickness is 10 nm or more: that is, 12 nm. Since the thickness exceeds 0.5 nm, the intermediate layer 7 is monolithic. If the thickness is 10 nm or more, the intermediate layer 7 becomes insulating, and serves as a barrier to the holes and the electrons. If the thickness of the intermediate layer 7 is 0.5 nm or more and less than 10 nm when the bands of the hole-transport layer 6 and the quantum dot layer 8 shift so that Fermi levels of the hole-transport layer 6 and the quantum dot layer 8 match, the band of the intermediate layer 7 also transforms in conformity with the hole-transport layer 6 and the quantum dot layer 8 facing each other across the intermediate layer 7, and an effective thickness of the intermediate layer 7 that the holes sense decreases. Hence, because of the tunneling effect, the holes are injected from the hole-transport layer 6 to the quantum dot layer 8. The tunneling effect decreases as the intermediate layer 7 becomes thicker. Hence, the voltage rises when the thickness of the intermediate layer 7 is 10 nm or more.

The present invention shall not be limited to the embodiments described above, and can be modified in various manners within the scope of claims. The technical aspects disclosed in different embodiments are to be appropriately combined together to implement another embodiment. Such an embodiment shall be included within the technical scope of the present invention. Moreover, the technical aspects disclosed in each embodiment are combined to achieve a new technical feature.

### REFERENCE SIGNS LIST

1 Light-Emitting Device, 2 Light-Emitting Element, 3 Array Substrate, 4 First Electrode, 6 (6a, 6b, and 6c) Hole-Transport Layer, 7 Intermediate Layer, 8 Quantum Dot Layer, 10 Electron-Transport Layer, 12 Second Electrode, 16 Quantum Dots

1. A light-emitting element, comprising:
a first electrode;
a second electrode;
a quantum dot layer provided between the first electrode and the second electrode, and containing quantum dots; and
a hole-transport layer provided between the quantum dot layer and the first electrode, and containing a compound ZnM₂O₄ (where an element M is a metal element).

2. The light-emitting element according to claim 1, wherein
the element M is at least one of cobalt, rhodium, and iridium selected from among metal elements in group 9.

3. The light-emitting element according to claim 1, wherein
the hole-transport layer is a mixture or a solid solution of two or more of a plurality of the compounds ZnM₂O₄ each having the element M of a different metal element.

4. The light-emitting element according to claim 1, wherein
the hole-transport layer is a first multilayer stack including a plurality of layers containing the compounds ZnM₂O₄, and, in the first multilayer stack, the compounds ZnM₂O₄, contained in the layers adjacent to one another, each have the element M of a different metal element.

5. (canceled)

6. The light-emitting element according to claim 1, wherein
the hole-transport layer has a thickness of 1 nm or more and 40 nm or less.

7. The light-emitting element according to claim 1, further comprising
an intermediate layer provided between the hole-transport layer and the quantum dot layer, and containing a compound L₂O₃ (where an element L is a metal element).

8. The light-emitting element according to claim 7, wherein
the intermediate layer is lower in electron affinity than the quantum dot layer.

9. The light-emitting element according to claim 7, wherein
the intermediate layer is higher in ionization potential than the quantum dot layer.

10. The light-emitting element according to claim 7, wherein
the element L is at least one of aluminium, gallium, and indium selected from among metal elements in group 13.

11. The light-emitting element according to claim 10, wherein
the intermediate layer has a crystal structure of a rhombohedron or a monoclinic crystal.

12. The light-emitting element according to claim 7, wherein
the intermediate layer has a thickness of 0.5 nm or more and less than 10 nm.

13. The light-emitting element according to claim 7, wherein
the intermediate layer is a mixture or a solid solution of at least two of a plurality of the compounds L₂O₃ each having the element L of a different metal element.

14. The light-emitting element according to claim 7, wherein
the intermediate layer is a second multilayer stack including a plurality of layers containing the compounds L₂O₃, and, in the second multilayer stack, the compounds L₂O₃, contained in the layers adjacent to one another, each have the element L of a different metal element.

15. The light-emitting element according to claim 1, wherein
the hole-transport layer contains two or more of a plurality of the compounds ZnM₂O₄ each having the element M of a different metal element.

16. A light-emitting element, comprising:
a first electrode;
a second electrode;
a quantum dot layer provided between the first electrode and the second electrode, and containing quantum dots; and
a hole-transport layer provided between the quantum dot layer and the first electrode, and containing a compound ZnM₂O₄ (where an element M is a metal element other than rhodium).

17. The light-emitting element according to claim 16, wherein
the element M is iridium.

18. The light-emitting element according to claim 16, further comprising
an electron-transport layer provided between the quantum dot layer and the second electrode.

19. A light-emitting element, comprising:
a first electrode;
a second electrode;
a quantum dot layer provided between the first electrode and the second electrode, and containing quantum dots; and
a hole-transport layer provided between the quantum dot layer and the first electrode, and containing a compound made of zinc, oxygen, and an element M including at least one element selected from among cobalt, rhodium, and iridium.

20. The light-emitting element according to claim 19, wherein
the element M includes at least two of elements selected from among cobalt, rhodium, and iridium.

21. The light-emitting element according to claim 19, further comprising
an intermediate layer provided between the hole-transport layer and the quantum dot layer, and containing a compound made of oxygen and an element L including at least one element selected from among aluminium, gallium, and indium.
